(19) United States
(12) Patent Application Publication
(10) Pub. No.: US 2009/0166852 A1
(43) Pub. Date: Jul. 2, 2009

(54) SEMICONDUCTOR PACKAGES WITH THERMAL INTERFACE MATERIALS

(76) Inventor: Chuan Hu, Chandler, AZ (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/967,860

(22) Filed: Dec. 31, 2007

(51) Int. Cl. H01L 23/34; H01L 21/48

(52) U.S. Cl. 257/707; 438/122; 257/713; 257/720; 361/708; 257/E23.08; 257/E21.499

(57) ABSTRACT

A method comprises providing a layer of nano particles between a semiconductor die and a slug; and sintering the layer of nano particles to provide thermal interface material to bond the semiconductor die to a heat spreader formed by the slug. The sintering temperature of the nano particles is around 50° C. to around 200° C.

### BACKGROUND

A semiconductor package may comprise one or more semiconductor dies that may be attached to a substrate. A die may be both electrically and mechanically coupled to a substrate using, for example, a flip-chip interconnect technique or by wirebonding in conjunction with a die-attach adhesive. Some semiconductor packages may use a heat spreader. Thermal interface material (TIM) may be utilized to attach a heat spreader to a semiconductor die. During manufacture (and perhaps use), a semiconductor die may be susceptible to a die stress or warpage. Further, TIM in a semiconductor package may be susceptible to, e.g., shear or peeling. Several factors may impact the die stress or the extent of any TIM delamination or cracking, including the thickness of the die, processing temperatures (e.g. during solder reflow), differences in coefficient of thermal expansion (CTE) between the die and substrate, as well as other factors.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIGS. 1 to 5 are schematic diagrams of an embodiment of a method that may be used to form a semiconductor package.

FIG. 6 is a schematic diagram of an embodiment of a flow chart of a method that may be used to form a semiconductor package.

### DETAILED DESCRIPTION

In the following detailed description, references are made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numbers refer to the same or similar functionality throughout the several views.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

The following description may include terms, such as upper, lower, top, bottom, first, second, etc. that are used for descriptive purposes only and are not to be construed as limiting.

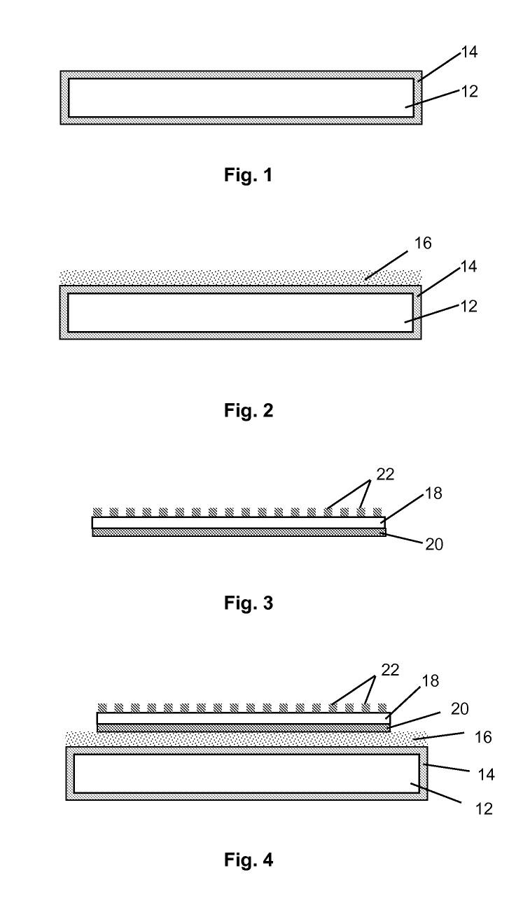

FIGS. 1 to 5 illustrate an exemplary embodiment of a method that may be used to form a semiconductor package. Referring to FIG. 1, in one embodiment, a slug 12 may be provided. The slug 12 may comprise, e.g., Ag, Cu, Au, CuW, diamond, SiC, Al or any other heat conductive material. In one embodiment, the slug 12 may have a thickness of about 0.5 mm to about 3 mm; however, some embodiments may utilize a different thickness. In one embodiment, a coating 14 may be provided on the slug 12 to prevent oxidation of the slug 12; however, in some embodiment, the coating 14 may not be required. In some embodiments, the coating 14 may be used to enhance bonding between the slug 12 and TIM, e.g., 28 of FIG. 5. For example, the coating 14 may comprise antioxidation materials, including, e.g., Ni, Au, Ag or any other antioxidation materials. In one embodiment, the coating 14 may be electroplated on the slug 12; however, in some embodiments, any other suitable methods, e.g., sputtering, spin coating, may be used to apply the coating 14 on the slug 12. In another embodiment, the coating layer 14 may have a thickness, e.g., around 1-10 μm; however, in some embodiments, the coating 14 may have any other suitable thickness.

Referring to FIG. 2, a layer of nano (e.g., Ag, Cu, Sn) particles 16 may be provided on the slug 12. In one embodiment, the layer of nano particles 16 may have a thickness of e.g., 10 micron; however, some embodiments may have a different thickness. In one embodiment, the nano particles 16 may be in a solvent. In another embodiment, the nano particles 16 may be in a paste; however, in some embodiments, the solvent may not be required. Any suitable methods may be used to form the nano particles 16, including, e.g., reduction from solvent, grinding or any other suitable methods. In one embodiment, a nano particle may have a grain size on a nanometer scale; however, in some embodiments, the nano particle may have any suitable size, e.g., from about 2 nm to a micron scale. While FIG. 2 illustrates an embodiment that may utilize nano Ag particles, some embodiments may utilize other materials, such as, Cu, Au, Al, Sn, In, SnAg, SnAgCu or any other materials, and/or any other alloy, or solder.

Referring to FIG. 3, a semiconductor die 18 may be prepared. In one embodiment, the die 18 may comprise a bump die that may comprise one or more bumps 22 to couple the die 18 to a substrate; however, in some embodiments, other interconnects may be utilized, including, e.g., gold stud bumps, land grid arrays (LGA), ball grid arrays (BGA), or any other conductive protrusions. In another embodiment, the die 18 may have a thickness from around 20 μm to around 100 μm; however, other embodiments may have any suitable thickness. While FIG. 3 illustrates one die 18, some embodiments may comprise more dies that may have a different arrangement. In another embodiment, a back side metallization (BSM) layer 20 may be deposited on, e.g., a lower side, of the die 18; however, in some embodiment, BSM layer 20 may not be required. For example, exemplary materials for BSM layer 20 may comprise titanium (Ti), nickel (Ni), silver (Ag) and/or gold (Au); however, in some embodiments, any other BSM materials may be utilized.

In one embodiment, BSM layer 20 may comprise a Ti layer that may have a thickness of around 50 nm, a Ni layer that may have a thickness of around 300 nm and an Ag finish or layer (e.g., an outer layer of the BSM layer 20) that may have a thickness of around 500 nm; however, some embodiments may comprise other materials, including, e.g., one or more from Cr, Ti, Ni, Au, Ag, or Pt that may each has a suitable thickness. In one embodiment, the BSM layer 20 may comprise an outer layer (e.g., Ag) that may have the same material as the nano particles 16 (e.g., Ag). In some embodiments, the BSM layer 20 may not be required, e.g., for other material system (e.g., reactive solder).

Referring to FIGS. 4 and 5, the die 18 may be provided on the slug 12, so that the BSM layer 20 may contact the nano particles 16. In one embodiment, the nano particles 16 may be sintered to form thermal interface material (TIM) 28 that may bond the die 18 and the slug 12. For example, the nano particles 16 may be sintered to form TIM 28 in inert air; however, in some embodiments, the inert air may not be required and the Ag nano particles 16 may be sintered in ambient air. In another embodiment, the Ag nano particles 16 may form TIM 28 at a temperature around 50° C. to around 200° C. For example, the Ag nano particles 16 may be sintered at a temperature around 100° C. to around 150° C.

In one embodiment, if the nano particles 16 are dispensed in a solvent, a vacuum oven or any other suitable device may be utilized to remove the solvent that is vaporized, e.g., during sintering of the Ag nano particles 16. In another embodiment, the TIM 28 may have a remelting temperature that may be higher than a melting temperature of Ag nano particles 16. In yet another embodiment, the TIM 28 may have a remelting temperature that may be higher than, e.g., around 900° C. Referring again to FIG. 5, the slug 12 may form a heat spreader 26, e.g., during sintering of the Ag nano particles 16. In another embodiment, the die 18 may be bonded to a substrate 24, wherein one or more bumps 22 may be mechanically and/or electrically coupled to the substrate 24.

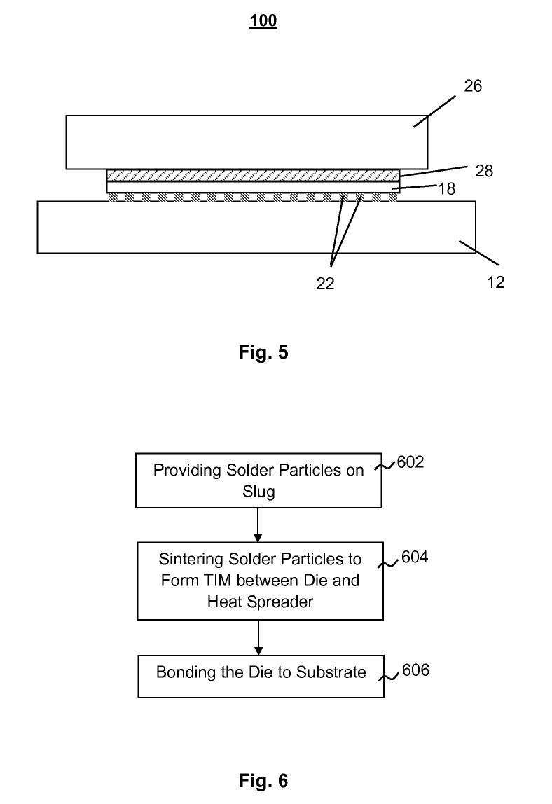

FIG. 6 illustrates an embodiment of a flow chart that may be utilized to form a semiconductor package. While the flow chart of FIG. 6 may be described with reference to the embodiments as shown in FIGS. 1 to 5, the description is not intended to be construed in a limiting sense. Referring to FIGS. 1,2 and 6, in block 602, slug 12 may be provided with nano particles 16. In one embodiment, the nano particles 16 may be formed by any suitable method, including, e.g., reduction from solvent, grinding or any other method to form particles having a grain size that may correspond to a nanometer scale; however, some embodiments may have a different grain size, e.g., to provide a reduced sintering or processing temperature and/or an increase remelting temperature. In another embodiment, the slug 12 may be further provided with a coating 14 that may prevent oxidation of the slug 12. In one embodiment, the coating 14 may enhance bonding between the heat spreader 26 formed by the slug 12 and the TIM 28 formed by the nano particles 16. In one embodiment, the nano particles 16 may comprise the same material (e.g., Ag) as the coating 14 (e.g., Ag).

Referring to FIGS. 3 to 6, in block 604, the nano particles 16 may be sintered to form TIM 28 between a semiconductor die 18 and the slug 12. In one embodiment, the TIM 28 may have a remelting temperature (e.g., around 900° C. or more) that may be higher than a melting temperature of the nano particles 16. In one embodiment, the nano particles 16 may be sintered at a processing temperature of around 50° C. to around 200° C.; however, in some embodiments, a different temperature may be applicable. In another embodiment, the nano particles 16 may be sintered in an inert environment; however, in some embodiments, the inert environment may not be required. In another embodiment, the die 18 may be coated with a layer of back side metallization 20 on one side that may contact with the nano particles 16. In yet another embodiment, the back side metallization layer 20 may comprise an outer layer that may comprise the same material as that of the nano particles 16 (e.g., Ag), e.g., to enhance bonding between the die 18 and the TIM 28 formed by the nano particles 16. In still another embodiment, the slug 12 may form a heat spreader 26 that may be bonded to the die 18 by the TIM 28. In block 606, the die 18 may be bonded to the substrate 24 by one or more bumps 22 on the other side of the die 18.

While the methods of FIGS. 1 to 6 are illustrated to comprise a sequence of processes, the methods in some embodiments may preform illustrated processes in a different order. Further, while the embodiments of FIGS. 1 to 6 are illustrates to comprise a certain number of dies, interconnects, substrates or other component, some embodiments may apply to a different number.

While certain features of the invention have been described with reference to embodiments, the description is not intended to be construed in a limiting sense. Various modifications of the embodiments, as well as other embodiments of the invention, which are apparent to persons skilled in the art to which the invention pertains are deemed to lie within the spirit and scope of the invention.

What is claimed is:

1. A method, comprising:
providing a layer of nano particles between a semiconductor die and a heat spreader; and
sintering the layer of nano particles to provide thermal interface material to bond the semiconductor die to the heat spreader.

2. The method of claim 1, wherein the layer of nano particles comprise one from a group comprising Ag, Cu, Al, SnAg, Au, SnAgCu, and In.

3. The method of claim 1, wherein the nano particles are sintered under a temperature of around 50° C. to around 200° C.

4. The method of claim 1, comprising:
providing a back side metallization layer on the semiconductor die, wherein the back side metallization layer comprises an outer layer that has the same metal as the nano particles.

5. The method of claim 4, wherein the backside metal comprises one from a group comprising Cr, Ti, Ni, Au, Ag, Pt.

6. The method of claim 1, comprising:
providing a coating on a slug to provide the heat spreader, wherein the coating comprises Ag and the nano particles comprise Ag.

7. The method of claim 6, wherein the coating comprises one from a group comprising Ni, Au, Ag.

8. The method of claim 1, wherein the layer of nano particles have a thickness of about 10 micron.

9. A semiconductor package, comprising:
a semiconductor die;
a layer of nano particles on the semiconductor die, wherein the layer of nano particles are sintered to provide thermal interface material to bond the die to a heat spreader.

10. The semiconductor package of claim 9, comprising:
a back side metallization layer provide on the semiconductor die, the back side metallization layer comprises an outer layer that has the same material as the nano particles.

11. The semiconductor package of claim 9, comprising:
a slug to form the heat spreader, the slug comprises a coating that comprises the same material as the nano particles.

12. The semiconductor package of claim 9, wherein the nano particles comprises one from a group comprising Ag, Cu, Al, SnAg, Au, SnAgCu, and In.

13. The semiconductor package of claim 9, wherein the layer of nano particles have a thickness from about 10 micron.

14. The semiconductor package of claim 9, wherein a nano particle has a grain size from a nanometer scale to a micron scale.

15. The semiconductor package of claim 9, wherein a nano particle has a melting temperature that is lower than a remelting temperature of the thermal interface material.
